(19) United States
(12) Patent Application Publication
(10) Pub. No.: US 2023/0318092 A1
(43) Pub. Date: Oct. 5, 2023

(54) 2D NON-CUBOIDAL METAL CAN BATTERIES

(71) Applicant: Meta Platforms Technologies, LLC, Menlo Park, CA (US)

(72) Inventors: Matthew Aaron, San Francisco, CA (US); Eunbit Cho, Seattle, WA (US); Ankur Gupta, Redwood City, CA (US); Jason Howard, Alpharetta, GA (US); Karthik Kadirvel, Cupertino, CA (US); Gregory Alan Roberts, Oakland, CA (US); Tianren Xu, Cupertino, CA (US)

(73) Assignee: Meta Platforms Technologies, LLC, Menlo Park, CA (US)

(21) Appl. No.: 18/182,223

(22) Filed: Mar. 10, 2023

Related U.S. Application Data
(60) Provisional application No. 63/327,745, filed on Apr. 5, 2022.

(51) Int. Cl. H01M 50/103; H01M 50/119; H01M 50/15; H01M 50/159; H01M 50/55; H01M 50/627; H01M 50/169; H01M 50/202; H01M 50/247

(52) U.S. Cl. CPC H01M 50/103; H01M 50/119; H01M 50/15; H01M 50/159; H01M 50/169; H01M 50/202; H01M 50/247; H01M 50/55; H01M 50/627; H01M 2220/30; H05K 5/0086

(57) ABSTRACT

A non-cuboidal battery having a cross-sectional area and a thickness may include a metal can housing, a metal lid coupled to the metal can housing, and an electrode stack disposed in the metal can housing. The thickness of the non-cuboidal battery can be substantially uniform over the cross-sectional area. The electrode stack may include a cathode layer stacked on an anode layer, and a separator layer disposed between the cathode layer and the anode layer. The electrode stack may be hermetically sealed by the metal can housing and the metal lid. A negative terminal that can be electrically coupled to the anode layer and a positive terminal that can be electrically coupled to the cathode layer may be disposed on an exterior side of the metal can housing or the metal lid.

### RELATED APPLICATIONS

This Application claims priority to U.S. Pat. Application No. 63/327,745, filed Apr. 5, 2022, which is incorporated herein by reference.

### BACKGROUND

Recent advances enabled wearable electronic devices, such as a headset device, that require considerable amounts of electrical energy. The electrical energy requirements of these devices coupled with the continual demand for smaller and/or non-uniformly shaped wearable electronic devices makes it difficult to adequately power the devices. Smaller conventional battery cells are useful and cost effective for larger and/or uniformly shaped devices. However, existing battery cells are available in limited sizes (e.g., thickness, and length), shapes, and configurations, and conventional battery cells are not always available to meet the requirements of wearable devices.

### BRIEF DESCRIPTION OF THE DRAWINGS

The detailed description is described with reference to the accompanying figures. In the figures, the left-most digit(s) of a reference number identifies the figure in which the reference number first appears.

FIG. 1 illustrates a 2D non-cuboidal metal can battery in accordance with an example of the present disclosure.

FIG. 2 illustrates a 2D non-cuboidal metal can battery in accordance with an example of the present disclosure.

FIG. 3 illustrates a 2D non-cuboidal metal can battery in accordance with an example of the present disclosure.

FIG. 4 illustrate a 2D non-cuboidal metal can battery in accordance with examples of the present disclosure

FIG. 5 illustrates 2D non-cuboidal metal can batteries in accordance with examples of the present disclosure.

FIG. 6 illustrates other example shapes of 2D non-cuboidal metal can batteries in accordance with examples of the present disclosure.

### DETAILED DESCRIPTION

While conventional battery cells are suitable for powering certain portable electronic devices. Some portable electronic devices, such as, by way of example and not limitation, extended reality headsets (e.g., augmented reality and/or virtual reality headsets, which may be referred to herein simply as “headsets”), glasses, watches, rings, or other wearable electronic devices may have requirements that are not possible or practical to meet with conventional battery cells. For example, conventional batteries, such as those used in laptops and cell phone batteries are not suitable for many wearable devices due to the high power requirements, small form factors and/or non-uniform geometries available to house batteries, and weight limitations of the wearable devices. For instance, some wearable devices (e.g., glasses, headsets, watches, rings, etc.) have housing or portions thereof that are thin and/or non-conventionally shaped and are not sized to accommodate traditional batteries such as those used in laptops and cell phones. Additionally, in order to improve user comfort, wearable devices often have and weight and space limitations that are not present (or are less restrictive) for laptops and cell phones.

This disclosure describes high capacity 2D non-cuboidal metal can batteries and techniques for manufacturing such high capacity 2D non-cuboidal metal can batteries. In some examples, the metal can batteries described in this disclosure may have a higher energy density (e.g., higher storage capacity per volume) than comparably sized batteries made using other manufacturing techniques (e.g., pouch batteries). In some examples, the 2D non-cuboidal metal can batteries may include non-conventional shapes, such as a semicircle, a trapezoid, a rectangle with chamfered corners, a rectangle with rounded corners, a ring, a semi-ring, an L-shape, and S-shape, a triangle, curvilinear, or other non-cuboidal shapes and can be sized and shaped fit into small and/or non-uniform spaces in housings of wearable devices (e.g., in frames and/or temples of a pair of glasses, in a strap or visor of a headset, in a housing or band of a wrist wearable, in a band of a ring, etc.). In some examples, 2D non-cuboidal metal can batteries according to this disclosure may be shaped and sized to fit with a portion of a housing, visor, strap, or other portion of a headset device. In some examples, 2D non-cuboidal metal can batteries according to this disclosure may be shaped and sized to fit with a portion of a frame or temple arm of a pair of glasses. Additionally, the 2D non-cuboidal metal can battery may have a thickness that is consistent and uniform along the length of the 2D non-cuboidal metal can battery.

In some examples, the 2D non-cuboidal metal can battery may be assembled by hermetically sealing an electrode stack within a metal can housing and a metal lid. The metal lid may be configured to be coupled to the metal can housing. In some examples, the metal lid may be secured to the metal can housing by welding (e.g., laser welding, friction welding, etc.), brazing, direct bonding, adhesive, crimping, mechanical fasteners, or other fastening mechanisms. A lip or flange may be formed around all or a portion of a perimeter of the metal lid and/or metal can housing. In some examples, the metal lid can be secured to the metal can housing by or along at least portion of the lip or flange (e.g., by welding along the flange(s), by crimping the flange(s), etc.). In some examples, the material for the metal can housing and the metal lid can include stainless steel, aluminum, titanium, nickel, or their alloys. The metal can housing and the metal lid can be made from the same materials. In other examples, the metal can housing and the metal lid can be made from different materials.

The electrode stack may be manufactured by stacking an anode layer on a cathode layer, and including a separator layer between the anode layer and the cathode layer. The electrode stack may include any number of anode layers, cathode layers, interleaved with intervening separator layers. A negative terminal is electrically coupled to the anode layer(s) and a positive terminal that is electrically coupled to the cathode layer(s) and protrudes through one or both of the metal can housing or the metal lid, and is disposed on an exterior side of the metal can housing or the metal lid. In some examples, the negative terminal and the positive terminal may be disposed on the same exterior side of the metal can housing or the metal lid to enable to the non-cuboidal battery to be coupled to closely positioned positive and negative terminals of an electronic component within the wearable device, thereby minimizing the need for lengthy wires or traces within the wearable device, and thereby further minimizing weight of the wearable device. In some examples, an electrolyte fill hole may be disposed on an exterior surface near an edge of the metal can housing or the metal lid.

The metal can housing may have a cross-sectional area that is defined by a width and a length. In some examples, the 2D non-cuboidal metal can battery may have a thickness that is substantially smaller than the length and width of the metal can housing. In at least one example, the length and width of the metal can housing may be at least five times the thickness of the 2D non-cuboidal metal can battery. In some examples, the electrode stack may have a complex, non-conventional shape that complements the non-conventional shape of metal can housing and/or the metal lid. By way of example and not limitation, suitable shapes of the cross-sectional area of the 2D non-cuboidal metal can battery include a semicircle, a trapezoid, a rectangle with a chamfered corner, a rectangle with a rounded corner, a ring, a semi-ring, an L-shape, an S-Shape, another curvilinear shape, or a triangle.

Any or all of the foregoing examples may be implemented alone or in combination with any one or more of the other examples described herein.

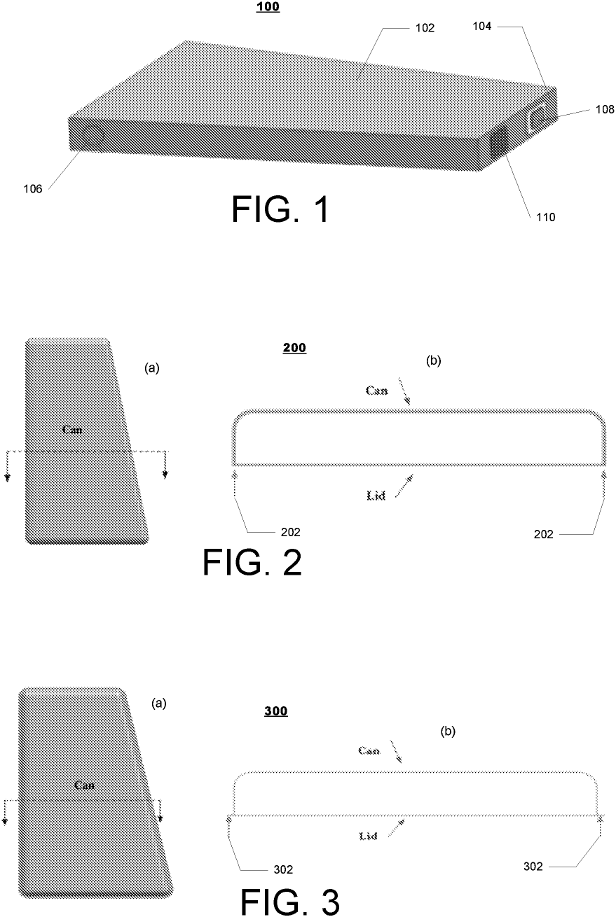

FIG. 1 illustrates a non-cuboidal metal can battery 100 including a metal can housing 102 and metal lid 104. The electrode stack (not shown) is secured within the metal can housing 102 and metal lid 104. Positive terminal 108 and negative terminal 110 are electrically coupled to the cathode layer (not shown) and anode layer (not shown) of the electrode stack (not shown). Furthermore, the positive terminal 108, the negative terminal 110, and an electrolyte fill hole 106 are disposed on exterior side surfaces of the non-cuboidal metal can battery 100. An electrolyte can be added to the non-cuboidal metal can battery 100 through the fill hole 106 and the non-cuboidal metal can battery 100 can be hermetically sealed.

FIG. 2 illustrates a 2D non-cuboidal metal can battery 200 that includes a metal can housing (or can) and a metal lid (or lid) that complements the metal can housing. The metal can housing can be secured to the metal lid by welding (e.g., laser welding, friction welding, etc.), brazing, direct bonding, adhesive, crimping, mechanical fasteners, or other fastening mechanisms along seams or contact points 202.

FIG. 3 illustrates a 2D non-cuboidal metal can battery 300 that includes a metal can housing (or can) and a metal lid (or lid) that complements the metal can housing. The metal can housing in this example includes a lip or flange 302 around all or a portion of an opening in the meal can housing. In this example, the and metal lid are secured together along all or portions of the lip or flange 302. The lid in this example can secured to the metal can housing via welding (e.g., laser welding, friction welding, etc.), brazing, direct bonding, adhesive, crimping, mechanical fasteners, or other fastening mechanisms.

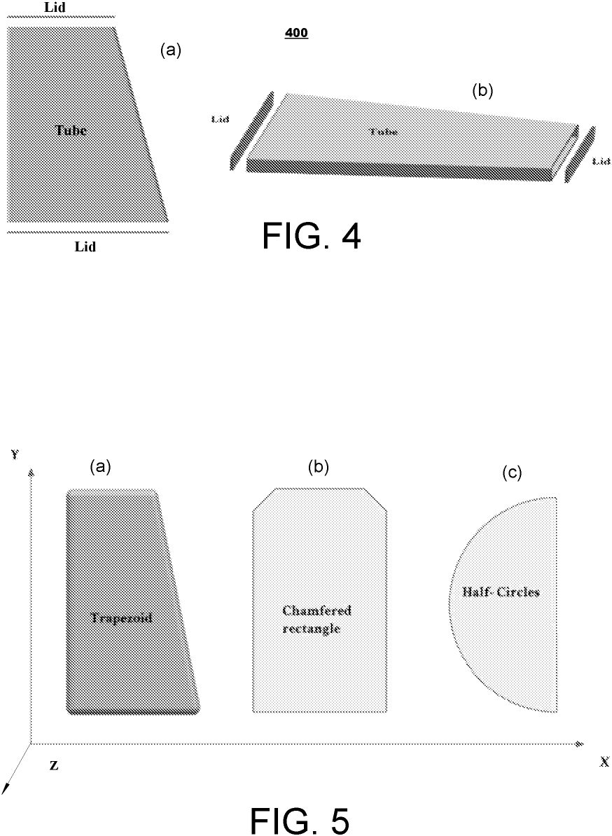

FIG. 4 illustrates a 2D non-cuboidal metal can battery 400 that includes a metal can housing (or tube) and two metal lids (or lids). The metal can housing can be the shape of a hollow tube that encases the electrode stack (not shown). The non-cuboidal metal can battery may include two metal lids that, when secured to the metal can housing, secure the electrode stack (not shown) within the metal can housing. As in the previous examples, the non-cuboidal metal can battery 400 of this example may include one or more flanges on the tube and/or one or both of the metal lids. The lids in this example may be secured to the metal can housing by welding (e.g., laser welding, friction welding, etc.), brazing, direct bonding, adhesive, crimping, mechanical fasteners, or other fastening mechanisms. An electrolyte fill hole may be disposed proximate an edge of either the metal can housing or one of the lids.

FIG. 5 illustrates three example 2D non-cuboidal metal can batteries with complex, non-conventional shapes. The length of non-cuboidal metal can batteries corresponds to the Y-axis, the width corresponds to the X-axis, and the thickness corresponds to the Z-axis. The thicknesses of each of the 2D non-cuboidal metal can batteries (a)-(c) are consistent along the lengths and/or widths of the respective 2D non-cuboidal metal can batteries (a)-(c). Unlike the thicknesses, the lengths and widths may vary, and form irregular, non-conventional 2D shapes in the x-y plane. In some examples, the thicknesses are substantially smaller than the widths and lengths. In some examples, the length and/or the width of the non-cuboidal metal can battery may be at least five times the thickness of the non-cuboidal metal can battery.

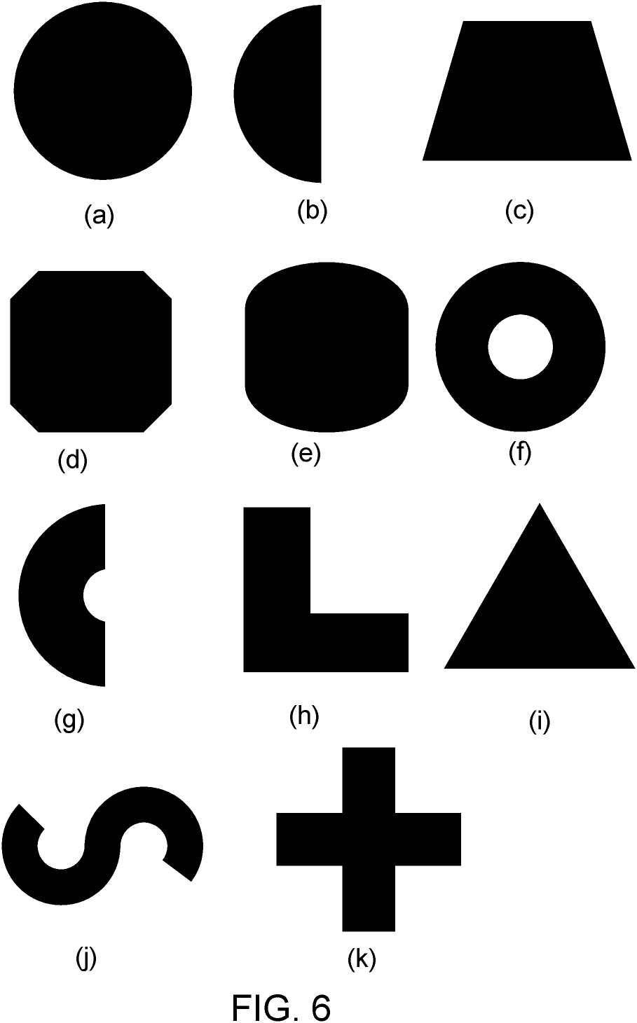

FIG. 6 illustrates other example shapes for 2D non-cuboidal metal can batteries according to this disclosure. The suitable shapes may include (a) a circle, (b) a semi-circle, (c) a trapezoid, (d) a rectangle with chamfered corners, (e) a rectangle with rounded corners, (f) a ring, (g) a semi-ring, (h) an L-shape, (i) a triangle, (j) an S-shape, and (k) a cross. Furthermore, in each instance, the electrode stack may have a shape that complements all or a portion of the shape of the 2D non-cuboidal metal can battery housing. Any or all of these example shapes may include a metal lid coupled to a metal can housing, with or without a flange, via welding (e.g., laser welding, friction welding, etc.), brazing, direct bonding, adhesive, crimping, mechanical fasteners, or other fastening mechanisms. Also, an electrolyte fill hole may be disposed proximate an edge of either the metal can housing or the lid in any of these examples.

### Conclusion

Although the discussion above sets forth example implementations of the described techniques, other architectures may be used to implement the described functionality, and are intended to be within the scope of this disclosure. Furthermore, although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

What is claimed is:

1. A non-cuboidal battery having a cross-sectional area and a thickness, the non-cuboidal battery comprising:
a metal can housing;
a metal lid coupled to the metal can housing;
an electrode stack disposed in the metal can housing, the electrode stack comprising:
an anode layer;
a cathode layer stacked on the anode layer; and
a separator layer interposed between the cathode layer and the anode layer, wherein the electrode stack is hermetically sealed by the metal can housing and the metal lid; and
a negative terminal electrically coupled to the anode layer and a positive terminal electrically coupled to the cathode layer,
wherein the negative terminal and the positive terminal are disposed on an exterior side of the metal can housing or the metal lid; and
wherein the thickness of the non-cuboidal battery is substantially uniform over the cross-sectional area.

2. The non-cuboidal battery of claim 1, wherein a shape of the electrode stack complements a shape of at least one of the metal can housing or the metal lid.

3. The non-cuboidal battery of claim 1, the metal can housing further comprising an electrolyte fill hole disposed in at least one of the metal can housing or the metal lid at a position proximate an edge of the at least one of the metal can housing or the metal lid.

4. The non-cuboidal battery of claim 1, wherein the cross-sectional area of the metal can housing is defined by a width and a length, and the width and the length are at least five times the thickness of the non-cuboidal battery.

5. The non-cuboidal battery of claim 1, wherein a shape of the cross-sectional area of the non-cuboidal battery comprises one of:
a semicircle;
a trapezoid;
a rectangle with a chamfered or rounded corner;
a ring;
a semi-ring;
an L-shape;
an S-shape; or
a triangle.

6. The non-cuboidal battery of claim 1, further comprising, a flange disposed around a perimeter of the metal can housing or the metal lid.

7. The non-cuboidal battery of claim 1, wherein the metal lid is a first metal lid, and the metal can housing includes a hollow tube,
the non-cuboidal battery further comprising a second metal lid, wherein the first metal lid is secured to a first end of the metal can housing, and the second metal lid is secured to a second side of the metal can housing opposite the first end of the metal can housing.

8. The non-cuboidal battery of claim 7, wherein the negative terminal and the positive terminal are disposed on an exterior surface of the second metal lid.

9. A method for manufacturing a non-cuboidal battery having a cross-sectional area and a thickness, the method comprising:
forming a metal can housing;
forming a metal lid configure to be coupled to the metal can housing;
forming an electrode stack comprising:
an anode layer;
a cathode layer; and
a separator layer, the separator layer interposed between the cathode layer and the anode layer; and
encasing the electrode stack in the metal can housing and the metal lid;
securing the metal can housing to the metal lid; and
forming a negative terminal that extends through at least one of the metal can housing or the metal lid and is electrically coupled to the anode layer, and a positive terminal that extends through at least one of the metal can housing or the metal lid and is electrically coupled to the cathode layer,
wherein the negative terminal and the positive terminal are disposed on an exterior side of the metal can housing or the metal lid; and
wherein the thickness of the non-cuboidal battery is substantially uniform over the cross-sectional area.

10. The method of claim 9, wherein a shape of the electrode stack complements a shape of at least one of the metal can housing or the metal lid.

11. The method of claim 9, wherein the metal lid is welded to the metal can housing.

12. The method of claim 9, the method further comprising forming an electrolyte fill hole disposed in at least one of the metal can housing or the metal lid at a position proximate an edge of the at least one of the metal can housing or the metal lid; and
filling the non-cuboidal battery with electrolyte through the electrolyte fill hole; and
hermetically sealing the non-cuboidal battery.

13. The method of claim 9, wherein the cross-sectional area of the metal can housing is defined by a width and a length, and the width and the length are at least five times the thickness of the non-cuboidal battery.

14. The method of claim 9, wherein a shape of the cross-sectional area of the non-cuboidal battery comprises one of:
a semicircle;
a trapezoid;
a rectangle with a chamfered or rounded corner;
a ring;
a semi-ring;
an L-shape;
an S-shape; or
a triangle.

15. The method of claim 9, wherein the metal can housing and metal lid are hermetically sealed by forming a flange around a perimeter of the metal can housing or the metal lid.

16. The method of claim 9, wherein metal lid is a first metal lid, and the metal can housing includes a hollow tube,
wherein securing the metal can housing to the metal lid includes:
securing the first metal lid to a first end of the metal can housing; and
securing a second metal lid to a second end of the metal can housing.

17. The method of claim 16, wherein the negative terminal and the positive terminal are disposed on an exterior surface of the second metal lid.

18. A wearable electronic device, comprising:
the non-cuboidal battery of claim 1; and
a battery housing that houses the non-cuboidal battery, wherein the battery housing includes a shape that compliments a shape of the non-cuboidal battery.

19. The wearable electronic device of claim 18, wherein the wearable electronic device includes glasses, a headset device, a wristwatch, or a ring.

20. The wearable electronic device of claim 19, wherein the battery housing is disposed in at least one of:
a frame of the glasses;
a strap or visor of the headset device;
a band of the wristwatch; or
a band of the ring.
